(19) United States
(12) Patent Application Publication
(10) Pub. No.: US 2026/0004868 A1
(43) Pub. Date: Jan. 1, 2026

(54) APPARATUSES AND METHODS FOR LINK LOADING INFORMATION INTO FUSE LATCHES

(71) Applicant: Micron Technology, Inc., Boise, ID (US)

(72) Inventor: Jacob Rice, Boise, ID (US)

(73) Assignee: Micron Technology, Inc., Boise, ID (US)

(21) Appl. No.: 19/247,421

(22) Filed: Jun. 24, 2025

Related U.S. Application Data
(60) Provisional application No. 63/664,603, filed on Jun. 26, 2024.

(51) Int. Cl. G11C 29/44; G11C 29/00

(52) U.S. Cl. CPC G11C 29/4401; G11C 29/789

(57) ABSTRACT

The present disclosure is generally directed to repair solutions for a semiconductor memory device and linking some of the repair solutions together. When fuse bus addresses (FBAs) are generated and transmitted to one or more fuse arrays, a start of a link loading operation is detected based on a respective FBA. The information that is stored at the fuses corresponding to the respective FBA is output for the respective FBA and for one or more subsequent FBAs that are included in the link loading operation. Thus, the same information is output during the link loading operation. Prior to the start of the link loading operation, and/or at the end of the link loading operation, information received from the one or more fuse arrays can be output.

### CROSS-REFERENCE TO RELATED APPLICATIONS

This application claims the filing benefit of U.S. Provisional Application No. 63/664,603, filed Jun. 26, 2024. This application is incorporated by reference herein in its entirety and for all purposes.

### BACKGROUND

Memory devices, such as dynamic random-access memory (DRAM), include an array of memory cells that may be organized into rows (word lines) and columns (bit lines). Information may be stored in the memory cells, typically as single bit of information as either a logical high (e.g., a “1”) or a logical low (e.g., a “0”). At various points in the manufacturing and use of a memory device, one or more memory cells may fail (e.g., become unable to store information, be inaccessible by the memory device, etc.) and may need to be repaired.

The memory device may perform repair operations on a row-by-row basis and/or a column-by-column basis. For example, during a column repair operation, a column containing a failed memory cell (which may be referred to as a defective column or a bad column) may be identified. The memory device may contain an additional column of memory (which may also be referred to as redundant column) which may be used in repair operations. During a repair operation, a column address associated with the defective column may be redirected, such that the column address points to a redundant column instead.

The number of repair operations performed in a memory device is expected to increase as the density of the memory cells in the memory device increases, due at least in part to a potentially higher number defective columns and rows. The increased density of memory cells may result in an increase in the amount of time needed to test the memory device and in an increase in the amount of time required to perform the necessary repair operations. One concern with the increase in the number of repair operations is the increase in the probability of creating defects in the memory device during the repair process (e.g., the fuse blowing process). A higher number of defects may result in a reduced production yield for memory devices.

### BRIEF DESCRIPTION OF THE DRAWINGS

Non-limiting and non-exhaustive examples are described with reference to the following Figures. The elements of the drawings are not necessarily to scale relative to each other. Identical reference numerals have been used, where possible, to designate identical features that are common to the figures.

FIG. 1 illustrates a block diagram of a semiconductor device according to an embodiment of the present disclosure;

FIG. 2 illustrates a block diagram representing a memory device according to an embodiment of the present disclosure;

FIG. 3 illustrates a flowchart of an example method of operating a memory device according to an embodiment of the present disclosure;

FIG. 4 illustrates an example timing diagram of signals involved in a linked repair operation of a memory device according to an embodiment of the present disclosure;

FIG. 5 illustrates a block diagram of an example fuse array and fuse logic circuit according to an embodiment of the present disclosure;

FIG. 6 illustrates a block diagram of a first example link loading flag logic circuit according to an embodiment of the present disclosure;

FIG. 7 illustrates a block diagram of a second example link loading flag logic circuit according to an embodiment of the present disclosure;

FIG. 8 illustrates a block diagram of an example fuse data select circuit according to an embodiment of the present disclosure; and

FIG. 9 illustrates an example schematic diagram of the fuse data select circuit shown in FIG. 8 according to an embodiment of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Semiconductor memory devices may store information in a plurality of memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns). The memory may further be organized into one or more memory banks, each of which may include a plurality of rows and columns. During operations, the memory device may receive a command and an address which specifies one or more rows and one or more columns and then execute the command on the memory cells at the intersection of the specified rows and columns (and/or along an entire row/column). As used herein, the term memory line may be used to refer to either a row or a column of the memory. It should be noted that the memory lines describe an organizational structure and do not necessarily have to be linear in shape. Embodiments of the present disclosure are described with respect to a particular type of memory line (e.g., a column) may be adapted for use with the other type of memory line (e.g., a row). While not shown or discussed herein, it should be understood that in order to adapt one of the described circuits from use in, for example, column repair operations to row repair operations, minor changes to the layout and function of the apparatuses and methods described herein may be required.

Certain memory cells may be defective, and memory lines containing one or more defective memory cells may generally be referred to as defective lines or bad lines. The defective lines may be incapable of storing information and/or may become otherwise inaccessible to the memory device. The memory device may carry out one or more types of repair operations to resolve the defective lines, which may be done on a line-by-line basis (e.g., a row-by-row basis and/or a column-by-column basis), or in some embodiments of the disclosure, in groups of lines.

Memory banks may generally include a number of additional memory lines, which may generally be referred to as redundant lines (e.g., redundant rows and/or redundant columns). During a repair operation, a memory line address (e.g., a row and/or column address) associated with a defective line may be redirected so that it is associated with one of the redundant lines instead. In some modes of operation, the repair operation may be a hard (or permanent) repair operation, where updated memory line address information is stored in the memory in a non-volatile form (e.g., stored in a manner that is maintained even when the memory device is powered down). For example, the memory device may include fuse banks, which may include fuses (and/or anti-fuses), each of which may have a state that can be permanently changed (e.g., when the fuse/anti-fuse is “blown”). The state of the fuses/anti-fuses in the fuse bank may, in part, determine which addresses are associated with which lines of memory. It may be both time and power intensive to blow a fuse/anti-fuse.

The present disclosure is generally directed to repair solutions for a semiconductor memory device and linking some of the repair solutions together. A repair solution is associated with the mapping of one or more defective memory lines (e.g., one or more defective rows or columns) to one or more redundant lines. In an example embodiment, two or more repair solutions can be linked together when the information in the two or more repair solutions is identical. When the fuse bus addresses (FBAs) are generated and transmitted to one or more fuse arrays, a start of a link loading operation is detected based on a respective FBA. The information read out of a fuse array that corresponds to the respective FBA is output for the respective FBA (which may be referred to as a link loading start address), and for one or more subsequent FBAs that are included in the link loading operation. The information corresponding to the one or more subsequent FBAs are disregarded or ignored. Thus, the same information is stored and output for the link loading start address and for the one or more subsequent FBAs in the link loading operation and latched in fuse latches that correspond to the FBAs. Information read out of the one or more fuse arrays prior to the start of the link loading operation, and/or at the end of the link loading operation, are output and stored in fuse latches that correspond to the FBAs associated with the fuses in the fuse arrays. One advantage to a link loading operation is that only one set of fuses, the set of fuses associated with the link loading start address, is blown in a fuse array. The sets of fuses associated with the subsequent FBAs in the link loading operation may not be blown. Blowing only one set of fuses can reduce the test time for a memory device. Additionally, blowing only one set of fuses may reduce the probability of creating defects in the fuse array that can result from the fuse blowing operation.

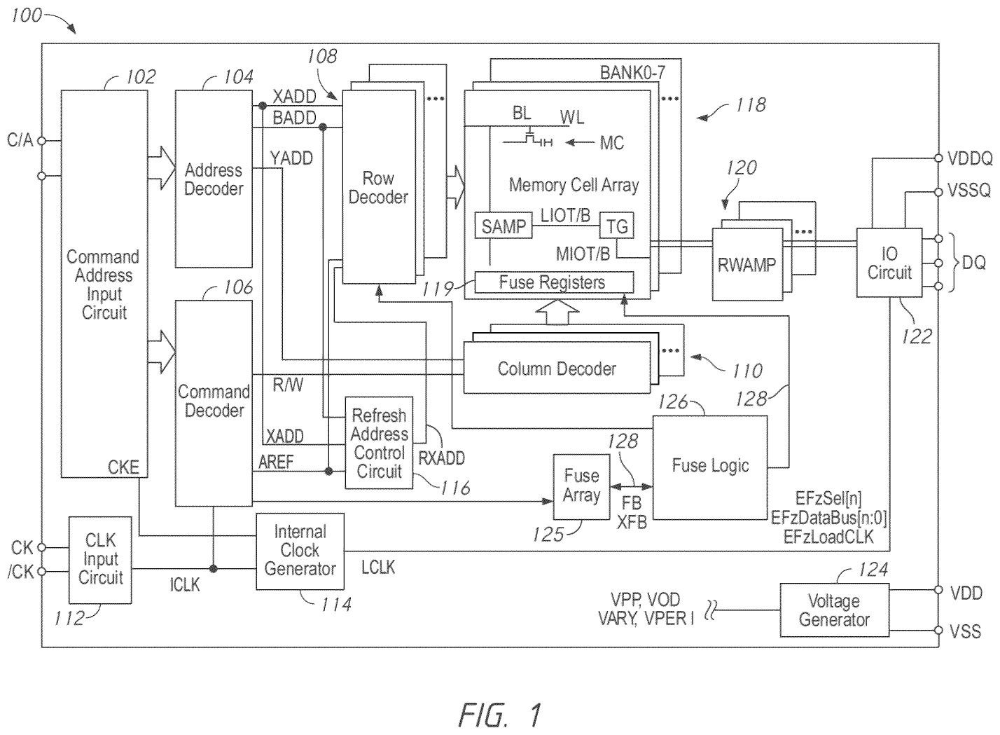

FIG. 1 is a block diagram of a semiconductor device 100 according to an embodiment of the disclosure. The semiconductor device 100 may be a semiconductor memory device, such as a DRAM device integrated on a single semiconductor chip. The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (e.g., rows), a plurality of bit lines BL and/BL (e.g., columns or digit lines), and a plurality of memory cells MC arranged at intersections of the plurality of word lines WL and the plurality of bit lines BL and/BL. The selection of the word line WL is performed by a row decoder 108 and the selection of the bit lines BL and/BL is performed by a column decoder 110. In the embodiment of FIG. 1, the row decoder 108 includes a respective row decoder for each memory bank and the column decoder 110 includes a respective column decoder for each memory bank. The bit lines BL and/BL are coupled to a respective sense amplifier (SAMP). Read data from the bit line BL or/BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL or/BL.

The semiconductor device also includes a fuse array 125, which contains a plurality of non-volatile storage elements which may store information about addresses in the memory array 118. The fuse array 125 includes non-volatile storage elements, such as fuses or anti-fuses. Each fuse may be in a first state where it is conductive and may be ‘blown’ to make the fuse insulating instead. Each anti-fuse may be in a first state which is non-conductive, until it is blown to make the anti-fuse conductive instead. Each fuse/anti-fuse may permanently change when it is blown. Each fuse/anti-fuse may be considered to be a bit, which is in one state before it is blown, and permanently in a second state after it is blown. For example, a fuse may represent a logical low before it is blown and a logical high after it is blown, while an anti-fuse may represent a logical high before it is blown and a logical low after it is blown. It should be understood that discussions of fuses as used herein may generally refer to either fuses or anti-fuses and that embodiments may use fuses, anti-fuses, or a combination thereof in the fuse array 125.

Specific groups of fuses/anti-fuses may be represented by a FBA, which may specify the physical location of each of the fuses/anti-fuses in the group within the fuse array 125. The group of fuses/anti-fuses associated with a particular FBA may in turn be used to encode an address associated with one or more memory cells of the memory array 118. For example, the state of a group of fuses/anti-fuses may represent a memory line address (e.g., either a row address XADD or a column address YADD). The address information in the fuse array 125 may be ‘scanned’ out along a fuse bus (FB and xFB) 128 to fuse registers 119. Each fuse register may be associated with a particular memory line of the memory array 118. In some embodiments, only the redundant memory lines of the memory array 118 (e.g., the rows/columns designated for use in repair operations) may be associated with one of the fuse registers 119. The address stored in a given group of fuses/anti-fuses (e.g., a group specified by an FBA) may be scanned out from the fuse array 125 along the fuse bus 128 and may be latched by a particular fuse register 119. The fuse logic circuit 126 may determine which address broadcast along the fuse bus 128 is latched in which fuse register 119. In this manner, an address stored in the fuse array 125 may be associated with a particular memory line of the memory array 118. When an incoming row/column address XADD or YADD matches the address stored in the fuse register 119, it may then direct access commands to the memory line associated with that fuse register 119.

The fuse registers 119 may each contain a number of fuse latches, each of which stores a bit of the stored memory line address. Since row addresses XADD and column addresses YADD may be different lengths, fuse registers 119 associated with redundant rows may have a different number of fuse latches than fuse registers 119 associated with redundant columns. Each of the fuse registers may be coupled to a fuse match circuit, which compares the incoming memory line address as part of an access operation to the address stored in the fuse register 119 to determine if there is a match. If there is a match, the redundant memory line associated with the fuse register 119 may be activated.

Some components of the match circuits, as well as other control logic of the fuse registers 119 may be shared between multiple fuse registers 119. For example, in some embodiments, match circuits may be shared by a number of different fuse registers 119. In some embodiments, a dynamic logic circuit may manage which of the fuse registers 119 coupled to a match circuit is active to provide the address stored in that fuse registers 119 for a comparison operation to determine if an accessed memory line address matches the stored address. In some embodiments, the dynamic logic circuit may also manage timing of the comparison operation.

The semiconductor device 100 may employ a plurality of external terminals that include command and address (C/A) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a row activation command ACT. When the row activation command ACT is received, a bank address BADD and a row address XADD are timely supplied with the row activation command ACT.

The semiconductor device 100 may receive an access command which is a read command. When a read command is received, a bank address BADD and a column address YADD are timely supplied with the read command, read data is read from memory cells in the memory array 118 corresponding to the row address XADD and column address YADD. For example, the row decoder may access the wordline associated with the row latch 119 which has an address which matches XADD. The read command is received by the command decoder 106, which provides internal commands so that read data from the memory array 118 is provided to the read/write amplifiers 120. The row decoder 108 may match the address XADD to an address stored in a row latch 119, and then may access the physical row associated with that row latch 119. The read data is output to outside from the data terminals DQ via the input/output circuit 122.

The semiconductor device 100 may receive an access command which is a write command. When the write command is received, a bank address BADD and a column address YADD are timely supplied with the write command, write data supplied to the data terminals DQ is written to a memory cells in the memory array 118 corresponding to the row address and column address. The write command is received by the command decoder 106, which provides internal commands so that the write data is received by data receivers in the input/output circuit 122. The row decoder 108 may match the address XADD to an address stored in a row latch 119, and then access the physical row associated with that row latch 119. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The semiconductor device 100 may also receive commands causing it to carry out an auto-refresh operation. The refresh signal AREF may be a pulse signal which is activated when the command decoder 106 receives a signal which indicates an auto-refresh command. In some embodiments, the auto-refresh command may be externally issued to the semiconductor device 100. In some embodiments, the auto-refresh command may be periodically generated by a component of the semiconductor device 100. In some embodiments, when an external signal indicates a self-refresh entry command, the refresh signal AREF may also be activated. The refresh signal AREF may be activated once immediately after command input, and thereafter may be cyclically activated at desired internal timing. Thus, refresh operations may continue automatically. A self-refresh exit command may cause the automatic activation of the refresh signal AREF to stop and return to an IDLE state.

The refresh signal AREF is supplied to the refresh address control circuit 116. The refresh address control circuit 116 supplies a refresh row address RXADD to the row decoder 108, which may refresh a wordline WL indicated by the refresh row address RXADD. The refresh address control circuit 116 may control a timing of the refresh operation and may generate and provide the refresh address RXADD. The refresh address control circuit 116 may be controlled to change details of the refreshing address RXADD (e.g., how the refresh address is calculated, the timing of the refresh addresses), or may operate based on internal logic. In some embodiments, the refresh address control circuit 116 may perform both auto-refresh operations, where the wordlines of the memory array 118 are refreshed in a sequence, and targeted refresh operations, where specific wordlines of the memory are targeted for a refresh out of sequence from the auto-refresh operations.

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122.

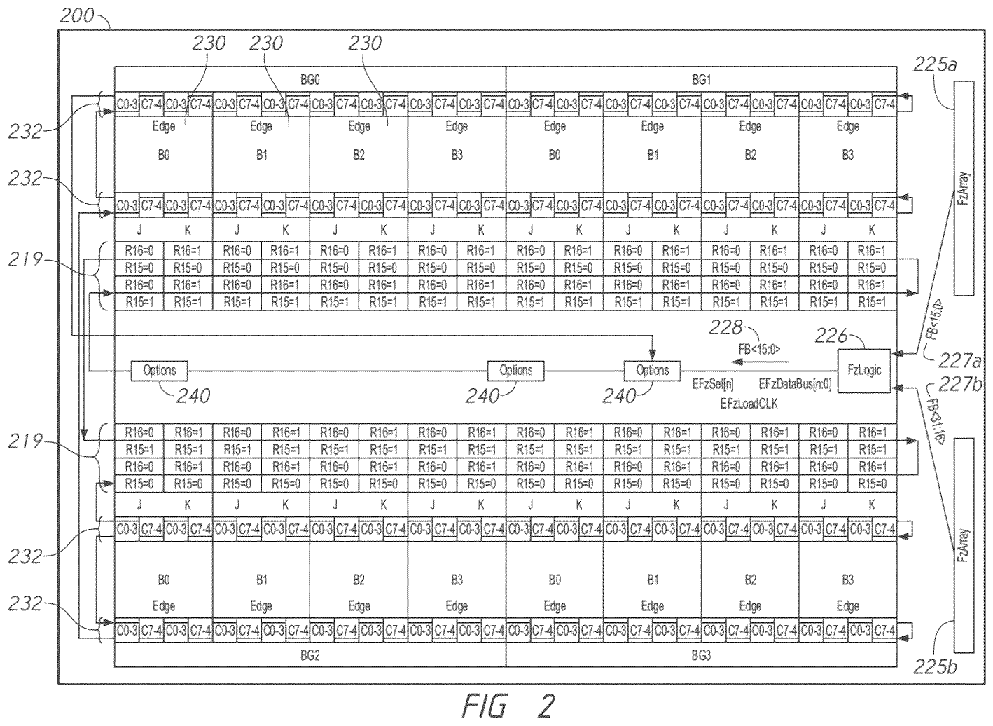

FIG. 2 is a block diagram representing a memory array 200 according to an embodiment of the present disclosure. FIG. 2 shows the transmission path of a fuse bus 228 from a pair of fuse arrays 225a and 225b through a memory array 200. In some embodiments, the memory array 200 may be an implementation of the memory array 118 of FIG. 1. However, the memory array 200 includes sixteen (16) banks 230 rather than the eight banks previously described with reference to the memory array 118. The 16 banks 230 are organized into four bank groups (BG0-BG3) of four banks 230 each. Each of the banks 230 is associated with a set of fuse latches such as row latches 219 and column latches 232.

Addresses may be scanned out along a fuse bus 228 from the fuse array 225a-b. In the particular embodiment of FIG. 2, there may be a pair of fuse arrays 225a and 225b. Each of the fuse arrays 225a, 225b may store a number of addresses, encoded in the conductive state of fuses and/or anti-fuses, which may be streamed out along the fuse bus 228 to the fuse registers such as the row latches 219 and column latches 232.

In some embodiments, the fuse array 225a may include anti-fuses, and may be a non-inverting fuse array (since the default value of the anti-fuses is a low logical level) and the fuse array 225b may include fuses and be an inverting fuse array. It may be necessary to ‘invert’ an address (e.g., swap low logical levels for high logical levels and vice versa) before providing an address based on the inverting fuse array 225b. It should be understood that other methods of organizing addresses in the fuse array(s) may be used in other embodiments. For example, a single fuse array may be used with only fuses, only anti-fuses, or a mix thereof.

During a broadcast operation, the fuse arrays 225a-b may broadcast the row addresses and the column addresses stored in the fuse arrays 225a-b along the fuse bus 228. In the particular embodiment of FIG. 2, during the broadcast operation the fuse logic circuit 226 may receive a portion of the addresses along fuse bus portion 227a from the fuse array 225a, and a portion of the addresses along fuse bus portion 227b from the fuse array 225b. The fuse logic circuit 226 may combine the addresses onto the fuse bus 228 by alternating whether the addresses from the first fuse bus portion 227a or the second fuse bus portion 227b are provided along the fuse bus 228. For clarity, the addresses provided along the fuse bus portion 227a may be referred to as ‘even’ addresses and the addresses provided along the fuse bus portion 227b may be referred to as ‘odd’ addresses. It should be understood that even and odd addresses refer to the fuse array 225a-b the address is stored in, and that both fuse bus portions 227a-b may include addresses with numerical values which are both even and odd.

The fuse logic circuit 226 may provide information along the fuse bus 228. The fuse logic circuit 226 may alternate between providing the even addresses from fuse bus portion 227a and the odd addresses from fuse bus portion 227b along the fuse bus 228. The fuse logic circuit 226 may also perform one or more operations based on the information of the fuse bus. For example, during a repair operation, the fuse logic circuit 226 may provide a select signal (e.g., such as a write signal) which indicates which fuse register a given address along the fuse bus 228 is latched in.

Another operation the fuse logic circuit 226 may participate in is a link loading operation. In some embodiments, one or more link loading operations occur during a broadcast operation. In some instances, a link loading operation links two or more repair solutions together (e.g., row address and/or column addresses) when the two or more repair solutions include identical information. In one embodiment, the two or more repair solutions are associated with sequential fuse bus addresses. The fuse logic circuit 226 is configured to detect a start of a link loading operation based on a link loading start address. The fuse logic circuit 226 is configured to output the information associated with the link loading start address (which may be referred to as link loading information), and for one or more subsequent FBAs that are included in the link loading operation. The information corresponding to the one or more subsequent FBAs may be disregarded or ignored.

The fuse logic circuit 226 may provide the information to the fuse bus 228, which may pass the information through one or more options circuits 240. The options circuits 240 may include various settings of the memory which may interact with the addresses along the fuse bus 228. For example, the options circuits 240 may include fuse settings, such as the test mode and power supply fuses. Information stored in the fuse arrays 225a-b may be latched and/or read by the options circuits 240, which may then determine one or more properties of the memory based on the options data provided along the fuse bus 228.

After passing through the options circuits 240 the fuse bus 228 may pass through the row latches 219 for all of the memory banks 230 before passing through the column latches 232 for all of the memory banks 230. As well as providing information (including address information) along the fuse bus 228, the fuse logic circuit 226 may also provide one or more select signals along the fuse bus 228. The select signals may be associated with a particular packet of information along the fuse bus and may determine which circuit along the fuse bus 228 the particular packet of information is associated with. For example, if a row latch select signal is in an active state, it may indicate that the packet of information is to be stored in a row latch 219. In some embodiments, this may overwrite an address already stored in the row latch 219 with the address from the fuse bus 228. Further select signals may be used to specify a particular location of the specific row latch 219 which is intended to store the packet of information (e.g., a bank group select signal, a bank select signal, etc.).

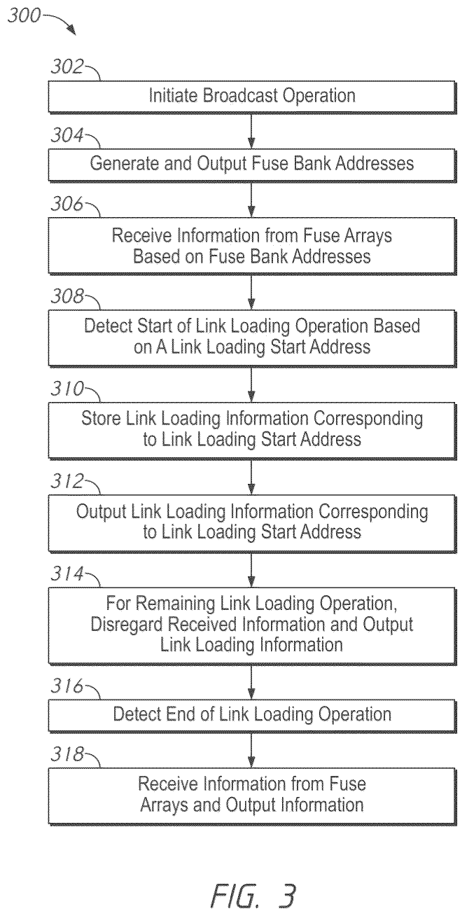

FIG. 3 illustrates a flowchart of an example method 300 of operating a memory device according to an embodiment of the present disclosure. The method 300 begins with the initiation of a broadcast operation at block 302. In a non-limiting nonexclusive example, a broadcast operation is performed during initialization of the memory device. At block 304, during the broadcast operation, FBAs may be generated and output to the fuse array to activate the fuse array (e.g., the fuse array 125 in FIG. 1 or the fuse arrays 225a, 225b in FIG. 2). Although FIG. 3 is described in conjunction with a fuse array, the method of FIG. 3 can be used with multiple fuse arrays.

At block 306, in response to activation, the fuse array may broadcast the information stored in the fuse array onto a fuse bus (e.g., the fuse bus 128 in FIG. 1 or the fuse buses 227a, 227b in FIG. 2). The information read out of the fuse array can be, for example, a row address, a column address, options data for one or more options circuits (e.g., option circuits 240 in FIG. 2), and/or bank data that is associated with a respective bank of the memory array (e.g., the memory array 118 in FIG. 1). In one embodiment, the FBAs are generated by the fuse logic circuit and the information read out of the fuse array is received by the fuse logic circuit (e.g., the fuse logic circuit 126 in FIG. 1 or the fuse logic circuit 226 in FIG. 2).

A start of a link loading operation is detected at block 308 based on a respective FBA (i.e., a link loading start address). A link loading operation can include two or more links (e.g., FBAs) that are linked together because the FBAs are associated with identical information (e.g., an identical repair solution for a row or a column). In one embodiment, the fuse logic circuit is configured to detect a start of a link loading operation.

The information (i.e., the link loading information) stored in the fuse array that is associated with the link loading start address is stored and output onto the fuse bus (blocks 310, 312). For example, the link loading information may be stored in, and output onto the fuse bus by the fuse logic circuit. At block 314, for each subsequent FBA in the link loading operation, the link loading information is output onto the fuse bus and the information that corresponds to the subsequent FBA is disregarded or ignored (e.g., a don't-care). In one embodiment, the link loading information that is output onto the fuse bus during the link loading operation is stored in respective fuse latches that are associated with the FBAs (e.g., the row latches 219, the column latches 232, or the options circuits 240 in FIG. 2).

The end of the link loading operation is detected at block 316. For example, the fuse logic circuit is configured to detect an end of a link loading operation. Next, as shown in block 318, after the link loading operation, additional information may be received from the fuse array and output onto the fuse bus. In one embodiment, the information that is output onto the fuse bus is stored in a respective fuse latch (e.g., the row latches 219, the column latches 232, or the options circuits 240 in FIG. 2).

The end of a link loading operation may be detected in one of several ways. In one embodiment, a respective FBA (also referred to as a link loading end address) may be detected. The link loading end address is the last FBA in the link loading operation. In another embodiment, a count can be used to indicate the end of the link loading operation. For example, a count can begin at the start of the link loading operation. The count may represent a count of a select signal or a clock signal. The end of the link loading operation may be determined based on the count reaching a specific value, where the specific value represents the end of the link loading operation. The specific value of the count may be referred to as an end count value.

The example method shown in FIG. 3 depicts blocks that occur in a particular sequence. Some of the blocks may be omitted in other embodiments, and/or some of the blocks can be performed in parallel. For example, block 304 may be omitted when the first FBA is a link loading start address. Additionally or alternatively, block 318 can be omitted when the last generated FBA is a link loading end address.

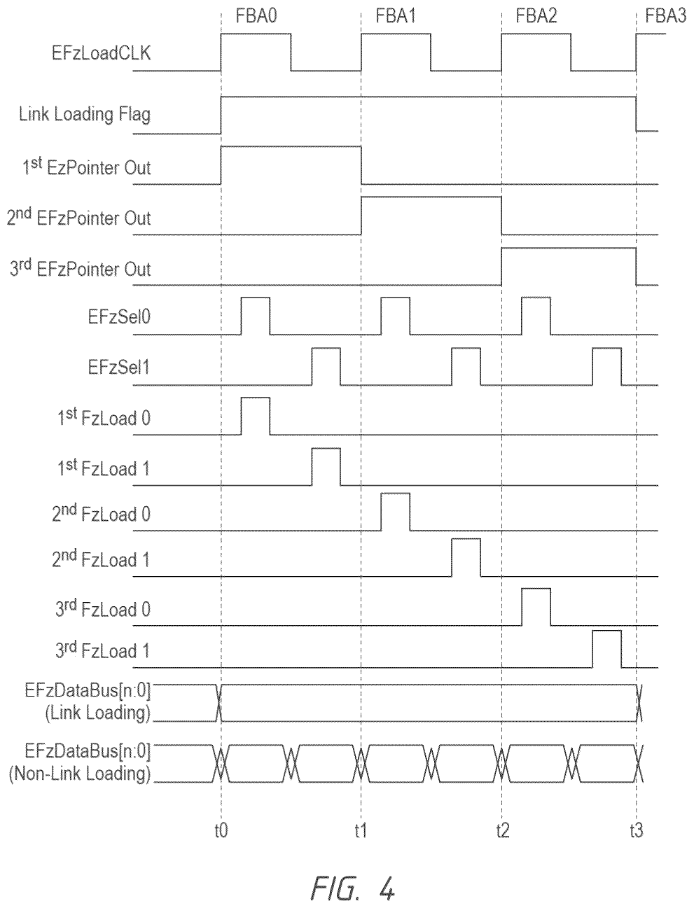

FIG. 4 illustrates an example timing diagram of signals involved in a link loading operation of a memory device according to an embodiment of the present disclosure. The example timing diagram is described with respect to two fuse arrays (e.g., fuse array 225a and fuse array 225b in FIG. 2), although other embodiments can have one or more fuse arrays. The example timing diagram depicts the signals during a time period of t0 through t3 when a link loading operation occurs. In the illustrated example, the link loading operation is associated with three FBAs (FBA0, FBA1, FBA2).

A fuse load clock signal (EFzLoadCLK) transitions from a high signal level (e.g., a “1”) to a low signal level (e.g., a “0”) during the time period t0 to t1, the time period t1 to t2, and the time period t2 to t3. Each transition to the high signal level can be associated with the output of a unique FBA. Thus, FBA0, FBA1, and FBA2 are generated during the time period t0 to t3. In one embodiment, the fuse load clock signal (EFzLoadCLK) is generated and output by a fuse logic circuit (e.g., the fuse logic circuit 126 of FIG. 1 or 226 of FIG. 2).

At time t0, when the fuse load clock signal transitions to the high signal level, the link loading flag signal transitions to a high signal level to indicate a start of a link loading operation. As will be described in more detail later, the detection of the start of the link loading operation is based on FBA0, which can be referred to as the link loading start address. The high signal level of the link loading flag signal is maintained during the link loading operation (during time period t0 to t3). At the end of the link loading operation, the link loading flag signal transitions to the low signal level. In one embodiment, the end of the link loading operation is detected based on FBA2, which is the link loading end address. In another embodiment, the end of the link loading operation is detected based on a received end count value. In one embodiment, the link loading signal is generated and used by a fuse logic circuit (e.g., the fuse logic circuit 126 of FIG. 1 or 226 of FIG. 2).

Three fuse pointer out signals are shown (1^{st} EFzPointer Out, 2^{nd} EFzPointer Out, and 3^{rd} EFzPointer Out). Each fuse pointer out signal is associated with a respective fuse latch. Based on FBA0, the first fuse pointer out signal (1^{st} EFzPointer Out) is associated with a first fuse latch. Based on FBA1, the second fuse pointer out signal (2^{nd} EFzPointer Out) is associated with a second fuse latch. Based on FBA2, the third fuse pointer out signal (3^{rd} EFzPointer Out) is associated with a third fuse latch. The data that is output onto the fuse bus based on FBA0, FBA1, FBA2 is latched at the first fuse latch, the second fuse latch, and the third fuse latch, respectively. In one embodiment, the fuse pointer out signals are generated and used by a fuse logic circuit (e.g., the fuse logic circuit 126 of FIG. 1 or 226 of FIG. 2).

A pulse occurs in a first fuse select signal (EFzSel0) and in a second fuse select signal (EFzSel1) during the time period between t0 to t1, the time period t1 to t2, and the time period t2 to t3. The pulses in the first fuse select signal (EFzSel0) and the second fuse select signal (EFzSel1) are offset in time from each other. In the illustrated embodiment, the pulses in the first fuse select signal (EFzSel0) occur when the fuse load clock signal is at the high signal level while the pulses in the second fuse select signal (EFzSel1) occur when the fuse load clock signal is at the low signal level.

The pulses in the first fuse select signal and in the second fuse select signal are associated with respect fuse latches. During the time period t0 to t1, data output onto the fuse bus is stored in the first fuse latch associated with the first fuse pointer out signal (1^{st} EFzPointer Out). During the time period t1 to t2, data output onto the fuse bus is stored in the second fuse latch associated with the second fuse pointer out signal (2^{nd} EFzPointer Out). During the time period t2 to t3, data output onto the fuse bus is stored in the third fuse latch associated with the third fuse pointer out signal (3^{rd} EFzPointer Out).

Pulses occur in six fuse load signals during the time period t0 to t3. During the time period t0 to t1, a pulse occurs in a first fuse load signal (1^{st} FzLoad 0) and in a second fuse load signal (1^{st} FzLoad 1). The pulse in the first fuse load signal occurs substantially at the same time as the pulse in the first select signal (EFzSel0). The pulse in the second fuse load signal occurs substantially at the same time as the pulse in the second select signal (EFzSel1). The first fuse load signal and the second fuse load signal are associated with data being loaded into the first fuse latch.

During the time period t1 to t2, a pulse occurs in a third fuse load signal (2^{nd} FzLoad 0) and in a fourth fuse load signal (2^{nd} FzLoad 1). The pulse in the third fuse load signal occurs substantially at the same time as the pulse in the first select signal (EFzSel0). The pulse in the fourth fuse load signal occurs substantially at the same time as the pulse in the second select signal (EFzSel1). The third fuse load signal and the fourth fuse load signal are associated with data being loaded into the second fuse latch.

During the time period t2 to t3, a pulse occurs in a fifth fuse load signal (3^{rd} FzLoad 0) and in a sixth fuse load signal (3^{rd} FzLoad 1). The pulse in the fifth fuse load signal occurs substantially at the same time as the pulse in the first select signal (EFzSel0). The pulse in the sixth fuse load signal occurs substantially at the same time as the pulse in the second select signal (EFzSel1). The fifth fuse load signal and the sixth fuse load signal are associated with data being loaded into the third fuse latch. In one embodiment, the fuse load signals are generated and used by a fuse logic circuit (e.g., the fuse logic circuit 126 of FIG. 1 or 226 of FIG. 2).

The fuse information signal (EfzDataBus[n:0] (Link Loading)) illustrates the effect of the link loading operation. During the time period t0-t1, the link loading information associated with the link loading start address (FBA0) is output as the fuse information signal. For the subsequent FBA1 and FBA2, the same link loading information is output as the fuse information signal. Since the same link loading information is output for FBA0, FBA1, and FBA2, only one set of fuses is blown (the set of fuses associated with FBA0). The sets of fuses associated with FBA1 and FBA2 do not have to be blown, which reduces test time and the possibility of creating defects in a fuse array during the fuse blowing operation.

In contrast, the fuse information signal (EFzDataBus[n:0] (Non-Link Loading)) depicts a conventional fuse information signal, where the fuse information signal includes data0, data1, data2, data3, data4, and data5. In the conventional techniques, three different sets of fuses are blown; a first set of fuses associated with FBA0, a second set of fuses associated with FBA1, and a third set of fuses associated with FBA2. Blowing the three different sets of fuses instead of one set of fuses for the link loading operation can result in increased test time and an increased probability of the formation of defects in one or more fuse arrays.

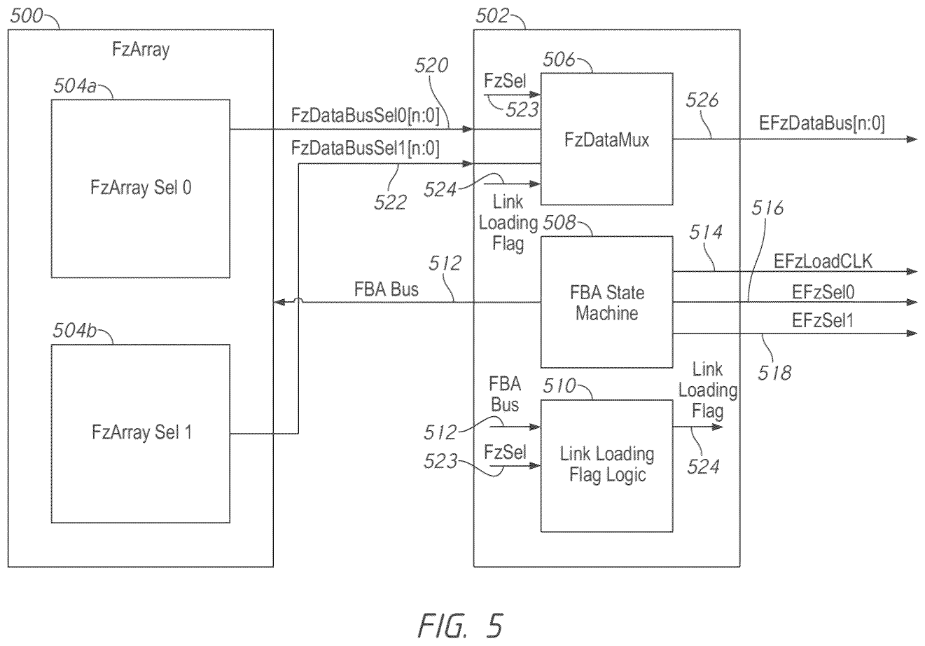

FIG. 5 illustrates a block diagram of an example fuse array 500 and a fuse logic circuit 502 according to an embodiment of the present disclosure. The fuse array 500 is depicted as including a pair of fuse arrays 504a, 504b, although other embodiments can include any number of fuse arrays. In some embodiments, the fuse array 500, the fuse logic circuit 502, and the pair of fuse arrays 504a, 504b may be an implementation of the fuse array 125 of FIG. 1 and the fuse logic 226 and the pair of fuse arrays 225a, 225b of FIG. 2, respectively.

The fuse logic circuit 502 includes a fuse data select circuit (FzDataMux) 506, a state machine 508, and a link loading flag logic circuit 510. The state machine 508 is configured to generate FBAs and transmit the FBAs to the fuse array 500 on an FBA bus 512. In one embodiment, during a broadcast operation, the state machine 508 increments the FBAs as the state machine 508 sequences through states until the state machine 508 reaches the last FBA. Each FBA is received by the fuse array 500 to access the fuses in the fuse array 500.

In the illustrated embodiment, the state machine 508 outputs a fuse load clock signal (EFzLoadCLK) on signal line 514, a first fuse select signal (EFzSel0) on signal line 516, and a second fuse select signal (EFzSel1) on signal line 518. The generation of the FBAs is based on the fuse load clock signal (EFzLoadCLK). The fuse load clock signal (EFzLoadCLK), the first fuse select signal (EFzSel0), and the second fuse select signal (EFzSel1) can be implementations of the fuse load clock signal (EFzLoadCLK), the EFzSel0 signal, and the EFzSel1 signal, respectively, shown in FIG. 4.

The first fuse select signal (EFzSel0) is used to activate the fuse latches that store information output onto the fuse data bus, while the second fuse select signal (EFzSel1) is used to activate the fuse latches that store information output onto the fuse data bus. In one embodiment, the second fuse select signal (EFzSel1) and the fuse load clock signal (EFzLoadCLK) are generated based on the first fuse select signal (EFzSel0). For example, the second fuse select signal (EFzSel1) is a complement of the first fuse select signal (EFzSel0). Thus, when the signal level of the first fuse select signal (EFzSel0) is at a high signal level (e.g., “1”) the second fuse select signal (EFzSel1) is at a low signal level (e.g., “0”), and vice versa. The first fuse select signal (EFzSel0) and the second fuse select signal (EFzSel1) may be combined to produce the fuse load clock signal (EFzLoadCLK).

Information stored in the first fuse array 504a is accessed and transmitted to the fuse logic circuit 502 on a first fuse data bus (FzDataBusSel0) 520 when a respective FBA represents a set of fuses in the first fuse array 504a. The information on the first fuse data bus 520 is received by the fuse data select circuit 506 in the fuse logic circuit 502. Information stored in the second fuse array 504b is accessed and transmitted to the fuse logic circuit 502 on a second fuse data bus (FzDataBusSel1) 522 when a respective FBA represents a set of fuses in the second fuse array 504b. The information is received by the fuse data select circuit 506 in the fuse logic circuit 502.

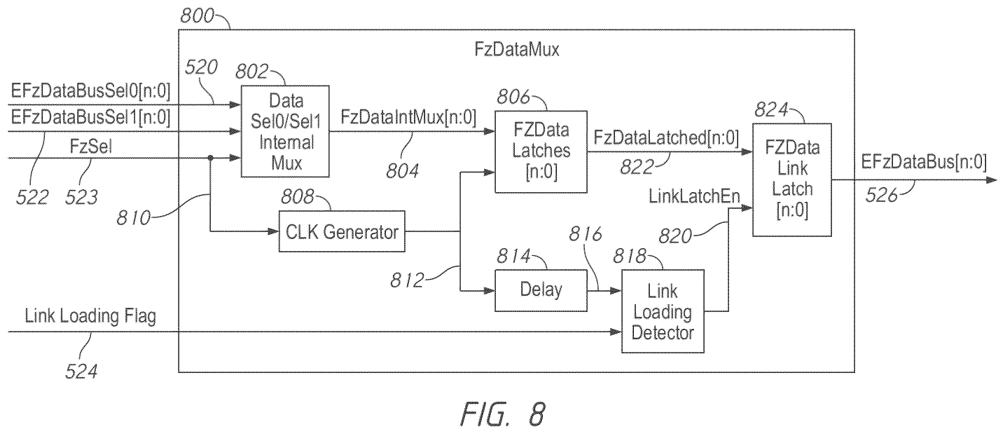

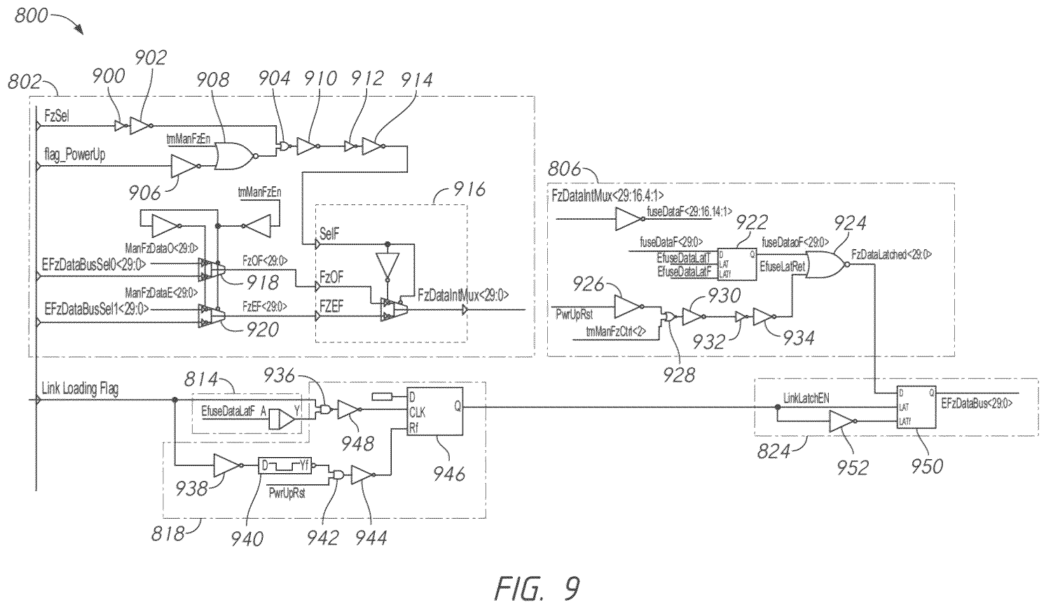

The fuse data select circuit 506 also receives the first fuse select signal (EfzSel0) on signal line 523 and a link loading flag signal on signal line 524. As will be described in more detail later, the fuse data select circuit 506 can output the information received on the first fuse data bus 520 and on the second fuse data bus 522 onto a fuse data bus (EFzDataBus[n:0]) 526 when the link loading flag signal is set to a first state (e.g., a low or (“0”) state). When the link loading flag signal set to a second state (e.g., a high or (“1”) state), a link loading operation is to be performed and the fuse data select circuit 506 repeatedly outputs the link loading information received on either the first fuse data bus 520 or the second fuse data bus 522 until the state of the link loading flag signal transitions back to the first state. The information received on the first fuse data bus 520 and on the second fuse data bus 522 during the link loading operation (e.g., after the link loading start address) are disregarded. When the link loading flag signal transitions back to the first state, the fuse data select circuit 506 outputs the information received on the first fuse data bus 520 and on the second fuse data bus 522. An example fuse data select circuit is described in more detail in conjunction with FIG. 8 and FIG. 9.

The link loading flag logic circuit 510 receives the FBAs on the FBA bus 512 and a fuse select signal (FzSel) on signal line 523 and outputs the link loading flag signal on signal line 524. In one embodiment, the fuse select signal (FzSel) received by the link loading flag logic circuit 510 is an internal fuse select signal that toggles between high and low states, which in turn toggles between the first fuse array 504a and the second fuse array 504b. The fuse select signal (FzSel) toggles between a first signal level (e.g., a high or “1”) and a second signal level (e.g., a low or “0”). The different signal levels are associated with the first fuse array 504a and the second fuse array 504b. For example, the first signal level (e.g., high or “1”) can be associated with the first fuse array 504a, where the FBA received when the fuse select signal level is high corresponds to an FBA of the first fuse array 504a. Similarly, the second signal level (e.g., low or “0”) can be associated with the second fuse array 504b, where the FBA received when the fuse select signal level is low corresponds to an FBA of the second fuse array 504b. For example, the fuse select signal (FzSel) can be either the first fuse select signal (EFzSel0) or the second fuse select signal (EFzSel1).

The link loading flag logic circuit 510 is configured to determine the start of a link loading operation and the end of the link loading operation. As discussed earlier, the start of a link loading operation is detected based on an FBA representing a link loading start address. When the link loading start address is received by the link loading flag logic circuit 510 on the FBA bus 512, the link loading flag logic circuit 510 is configured to transition the state of the link loading flag signal from a first state (e.g., a low or “0”) to a second state (e.g., high or “1”).

The link loading flag logic circuit 510 may detect the end of the link loading operation in one of several ways. The end of the link loading operation can be detected based on an FBA that is received on the FBA bus 512 representing a link loading end address. Alternatively, the end of the link loading operation may be determined based on a receipt of an end count value that represents the end of the link loading operation. When the link loading flag logic circuit 510 detects the end of the link loading operation, the link loading flag circuit is configured to transition the state of the link loading flag signal to the first state (e.g., low or “0”) to indicate the end of the link loading operation.

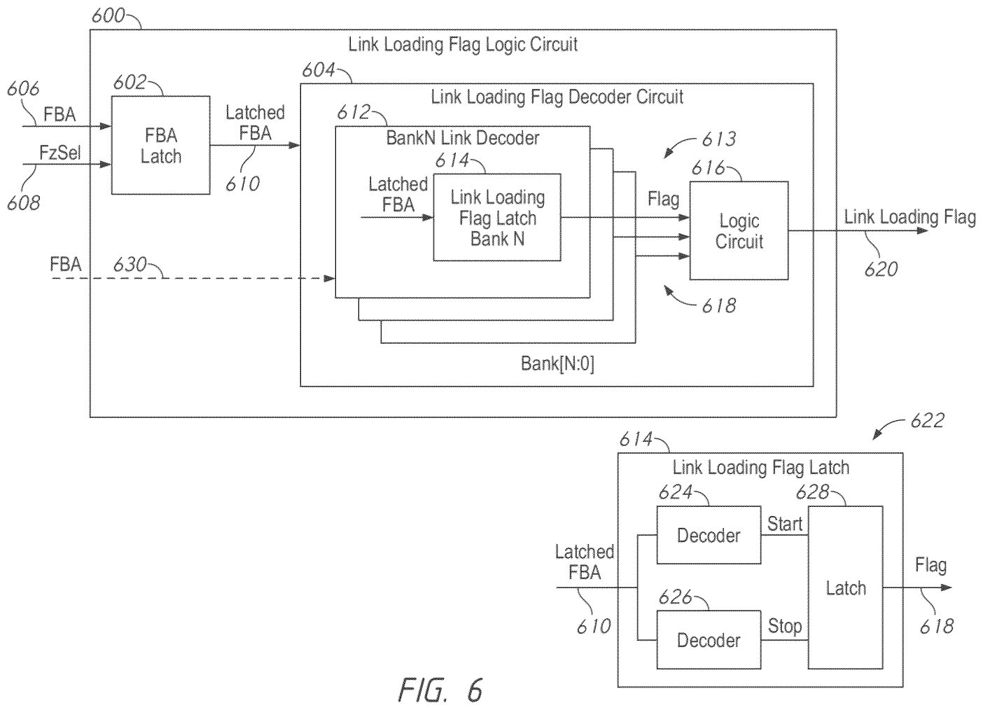

FIG. 6 illustrates a block diagram of a first example link loading flag logic circuit 600 according to an embodiment of the present disclosure. The link loading flag logic circuit 600 includes an FBA latch circuit 602 and a link loading flag decoder circuit 604. In some embodiments, the link loading flag logic circuit 600 may be an implementation of the link loading flag logic circuit 510 of FIG. 5.

The FBA latch circuit 602 receives the FBAs on signal line 606 (e.g., the FBA bus 512 of FIG. 5) and the internal fuse select signal (FzSel) on signal line 608 (e.g., the signal line 523 of FIG. 5). The FBA latch circuit 602 can include one or more latches that are configured to store or latch the FBAs. The FBA latch circuit 602 latches each FBA that is output from a fuse logic circuit (e.g., the state machine 508 in FIG. 5).

The FBA latch circuit 602 outputs a latched FBA to the link loading flag decoder circuit 604 on signal line 610. The link loading flag decoder circuit 604 includes one or more link decoder circuits 612. In the embodiment of FIG. 6, the link loading flag decoder circuit 604 is shown as including N banks 613 of link decoder circuits 612, where N is a number that is greater than zero. Each link decoder circuit 612 includes a link loading flag latch circuit 614. Each link loading flag latch circuit 614 is configured to detect a link loading start address that indicates a start of a link loading operation and a link loading end address that indicates an end of the link loading operation. In one embodiment, each bank 613 of the link loading flag latch circuit 614 is associated with a distinct portion of the fuses in the fuse array, and each bank is programmed with a unique link loading start address and a unique link loading end address.

Each bank 613 of the link decoder circuit 612 is configured to output a flag signal (Flag) to a logic circuit 616 on respective flag signal line 618. The signal level of all of the flag signals is set to a first state (e.g., low or “0”) when a link loading operation is not detected or in process. When a link loading flag latch circuit 614 in a particular bank 613 detects a link loading start address, the corresponding link loading flag latch circuit 614 sets the signal level of its flag signal (Flag) to a second state (e.g., high or “1”). The signal level of that flag signal remains in the second state until that link loading flag latch circuit 614 detects the link loading end address and sets the signal level of its flag signal to the first state (e.g., low of “0”).

The logic circuit 616 is configured to receive all of the flag signals from the banks 613 of link decoder circuits 612 and output the link loading flag signal on signal line 620 (e.g., signal line 524 in FIG. 5). In a non-limiting nonexclusive example, the logic circuit 616 is an OR circuit. The logic circuit 616 may be implemented as a different type of circuit in other embodiments.

An example block diagram of each link loading flag latch circuit 614 is shown in the expanded view 622. The link loading flag latch circuit 614 includes a first decoder circuit 624 and a second decoder circuit 626 that each receive the latched FBA on the signal line 610. The first decoder circuit 624 is configured to decode the received FBA to determine whether the latched FBA is a link loading start address. When the first decoder circuit 624 detects a link loading start address, the first decoder circuit 624 changes a state of a start signal (Start) to indicate the start of a link loading operation. The start signal is received by a latch circuit 628, which in turn outputs the flag signal on signal line 618. For example, when the first decoder circuit 624 detects a link loading start address, the first decoder circuit 624 changes the state of the start signal from a first state (e.g., low or “0”) to a second state (e.g., high or “1”). In response to the start signal transitioning to the second state, the latch circuit 628 changes the state of the flag signal to a state that indicates the start of a link loading operation.

The second decoder circuit 626 is configured to decode the received FBA to determine whether the latched FBA is a link loading end address. When the second decoder circuit 626 detects the link loading end address, the second decoder circuit 626 changes a state of a stop signal (Stop) to indicate the end of the link loading operation. The stop signal is received by the latch circuit 628, and the latch circuit 628 responsively changes the state of the flag signal. For example, when the second decoder circuit 626 detects the link loading end address, the second decoder circuit 626 changes the state of the stop signal from a first state (e.g., low or “0”) to a second state (e.g., high or “1”). In response to the stop signal transitioning to the second state, the latch circuit 628 changes the state of the flag signal to a state that indicates the end of the link loading operation. In one embodiment, the stop signal may reset the latch circuit 628, which causes the flag signal to change state.

In another embodiment, the link loading flag decoder circuit 604 can receive the FBAs directly from a fuse logic circuit on signal line 630 (e.g., the state machine 508 of FIG. 5). The FBA latch circuit 602 and the signal lines 606, 608, 610 may be omitted in such embodiments.

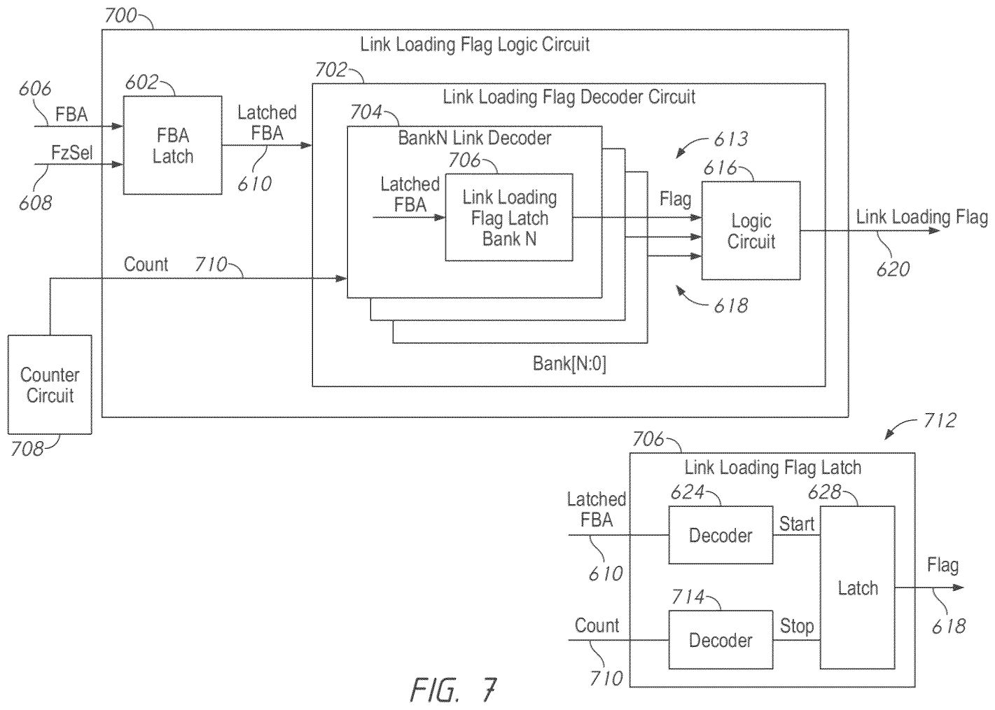

FIG. 7 illustrates a block diagram of a second example link loading flag logic circuit 700 according to an embodiment of the present disclosure. The link loading flag logic circuit 700 includes some of the same components that are shown in FIG. 6. For brevity, these same components are not described in detail in conjunction with FIG. 7.

The link loading flag logic circuit 700 includes a link loading flag decoder circuit 702. The link loading flag decoder circuit 702 includes one or more link decoder circuits 704. Similar to the embodiment of FIG. 6, the link loading flag decoder circuit 702 is shown as including N banks 613 of link decoder circuits 704, where N is a number that is greater than zero. Each link decoder circuit 704 includes a link loading flag latch circuit 706.

The link loading flag latch circuit 706 in each link decoder circuit 704 is configured to detect a link loading start address based on the latched FBAs that are received on the signal line 610. The link loading flag latch circuit 706 is further configured to detect the end of a link loading operation based on a count value that is received from a counter circuit 708. The counter circuit 708 is shown as an external counter circuit that is not implemented within the link loading flag logic circuit 700. In other embodiments, the counter circuit 708 may be implemented within the link loading flag logic circuit 700.

In one embodiment, the counter circuit 708 is configured to count the fuse select signal (FzSel) on signal line 608, although the counter circuit 708 may be configured to count another signal (e.g., a clock signal) in other embodiments. A count signal (Count) is output from the counter circuit 708 on signal line 710. The count signal is received by the link loading flag decoder circuit 702. In the illustrated example, the count signal may be shared by the one or more link loading flag latch circuits 706.

An example block diagram of each link loading flag latch circuit 706 is shown in the expanded view 712. The link loading flag latch circuit 706 includes the first decoder circuit 624 that receives the latched FBA on the signal line 606, and a third decoder circuit 714 that receives the count signal on signal line 710. The third decoder circuit 714 is configured to decode the count value to determine whether the count value is set to an end count value. When the third decoder circuit 714 determines the count value is set to the end count value, the third decoder circuit 714 changes a state of a stop signal (Stop) to indicate the end of the link loading operation. The stop signal is received by the latch circuit 628, which in turn outputs the flag signal. For example, when the third decoder circuit 714 detects the stop count, the third decoder circuit 714 changes the state of the stop signal from a first state (e.g., low or “0”) to a second state (e.g., high or “1”). In response to the stop signal transitioning to the second state, the latch circuit 628 changes the state of the flag signal to a state that indicates the end of a link loading operation. In one embodiment, the stop signal may reset the latch circuit 628, which causes the flag signal to change state.

Like the link loading flag decoder circuit 604 of FIG. 6, the link loading flag decoder circuit 702 of FIG. 7 can receive the FBAs directly from a fuse logic circuit (e.g., the state machine 508 of FIG. 5). The FBA latch circuit 602 and the signal lines 606, 608, 610 may be omitted in such embodiments.

FIG. 8 illustrates a block diagram of a fuse data select circuit 800 according to an embodiment of the present disclosure. A data multiplexer circuit (Data Sel0/Sel1 Internal Mux) 802 in the fuse data select circuit 800 is configured to receive information stored in the first fuse array on the first fuse data bus (FzDataBusSel0[n: 0]) 520, information stored in the second fuse array on the second fuse data bus (FzDataBusSel1) 522, and the internal fuse select signal (FzSel) on the signal line 523. In some embodiments, the first fuse array, the second fuse array, and the internal fuse select signal (FzSel) may be an implementation of the first fuse array 504a, the second fuse array 504b, and the internal fuse select signal (FzSel) shown in FIG. 5, respectively.

The data multiplexer circuit 802 outputs onto signal line 804 either the information received on the first fuse data bus 520 or the second fuse data bus 522 based on the toggling of the fuse select signal (FzSel). The output signal FzDataIntMux [n:0] is received by fuse data latches circuit (FzData Latches [n:0]) 806. The fuse data latches circuit 806 can include one or more latch circuits that latch the information received in the output signal FzDataIntMux [n:0].

The fuse select signal (FzSel) is also received by a clock generator circuit (CLK Generator) 808 on signal line 810. The clock generator circuit 808 outputs a clock signal on signal line 812 that is received by the fuse data latches circuit 806 and a delay circuit 814. A delayed clock signal is output from the delay circuit 814 on signal line 816 and received by a link loading detector circuit 818. The link loading flag signal is received by the link loading detector circuit 818 on signal line 524. The link loading detector circuit 818 is configured to output a link latch enable signal (LinkLatchEn) on signal line 820. The link latch enable signal is set to a first state (e.g., a low or “0”) when the link loading flag signal indicates a link loading operation is not starting or is not in process. When the link latch enable signal is set to the first state, the data signal (FzDataLatched [n:0]) output from the fuse data latches circuit 806 on signal line 822 is not latched and essentially passes through the fuse data link latch circuit (FzDataLinkLatch [n:0]) 824 and is output onto the fuse data bus (EFzDataBus [n:0]) 526.

When a link loading operation is starting or is in process, the link latch enable signal transitions to a second state (e.g., high or “1”), which causes the fuse data link latch circuit 824 to latch the information (the link loading information) received on signal line 822. During the link loading operation, the fuse data link latch circuit 824 repeatedly outputs the latched information (i.e., the link loading information) onto the fuse data bus 526. Although information is received on signal line 520 and signal line 522, and the information on signal line 822 corresponds to the information received on signal line 520 and signal line 522, the information repeatedly output on the fuse data bus 526 is the same information (i.e., the latched link loading information) during the link loading operation. When the link loading operation ends, the link latch enable signal transitions back to the first state, which causes the fuse data link latch circuit 824 to stop latching the link loading information. The information received on signal line 822 can pass through the fuse data link latch circuit 828 to the fuse data bus 526.

There can be some delay between receiving the information on the first fuse data bus 520 and the second fuse data bus 522 and latching the information in the fuse data latches circuit 806. The delay circuit 814 is configured to compensate for the delay by delaying when the link latch enable signal transitions to a signal level that causes the fuse data link latch 824 to latch the link loading information received on signal line 822. The delay circuit 814 can ensure the correct link loading information is latched in the fuse data link latch circuit 824.

FIG. 9 illustrates an example schematic diagram of the fuse data select circuit 800 shown in FIG. 8 according to an embodiment of the present disclosure. As described earlier, a fuse data select circuit 800 includes the data multiplexer circuit 802, the fuse data latches circuit 806, the delay circuit 814, the link loading detector circuit 818, and the fuse data link latch circuit 824. With respect to the data multiplexer circuit 802, the fuse select signal (FzSel) is received by a first inverter circuit 900 and a second inverter circuit 902 connected in series. A first input of a first NOR circuit 904 is connected to an output of the second inverter circuit 902. A flag_PowerUp signal is received by a third inverter circuit 906 and output to a first input of a second NOR circuit 908. The output of the second NOR circuit 908 is received at a second input of the first NOR circuit 904. An output of the first NOR circuit 904 is received at an input of a fourth inverter circuit 910. A fifth inverter circuit 912 and a sixth inverter circuit 914 are connected in series to the output of the fourth inverter circuit 910. An output of the sixth inverter circuit 914 is connected to a first input of a first multiplexer circuit 916. The output of the sixth inverter circuit 914 functions as a select signal for the first multiplexer circuit 916.

The data multiplexer circuit 802 further includes a second multiplexer circuit 918 that receives the information read from the first fuse array (EFzDataBusSel0[n:0]) and a third multiplexer circuit 920 that receives the information read from the second fuse array (EFzDataBusSel1 [n:0]). The output of the second multiplexer circuit 918 is received at a second input of the first multiplexer circuit 916. The output of the third multiplexer circuit 920 is received at a third input of the first multiplexer circuit 916.

The fuse data latches circuit 806 includes a first flip flop circuit 922 that receives the latched information from the data multiplexer circuit 802. An output of the first flip flop circuit 922 is received at a third NOR circuit 924. The output of the third NOR circuit 924 is the data signal FzDataLatched [n:0] that is received at the fuse data link latch circuit 824.

The fuse data latches circuit 806 further includes a seventh inverter circuit 926 that receives a power up reset signal (PwrUpRst). The output of the seventh inverter circuit 926 is received at a first input of a fourth NOR circuit 928. The output of the fourth NOR circuit 928 is received at an input of an eighth inverter circuit 930. A ninth inverter circuit 932 and a tenth inverter circuit 934 are connected in series to the output of the eighth inverter circuit 930. An output of the tenth inverter circuit 934 is received at a second input of the third NOR circuit 924.

The output of the delay circuit 814 is received at a first input of a NAND circuit 936 of the link loading detector circuit 820. A second input of the NAND circuit 936 and an eleventh inverter circuit 938 each receive the link loading flag signal. The output of the eleventh inverter circuit 938 is received at a clock generator circuit 940. The output of the clock generator circuit 940 is received at a first input of an AND circuit 942. The second input of the AND circuit 942 receives the power up reset signal PwrUpRst. The output of the AND circuit 942 is received at a twelfth inverter circuit 944, and the output of the twelfth inverter circuit 944 is received at a first input of a second flip flop circuit 946. The output of the NAND circuit 936 is received at a thirteenth inverter circuit 948, and the output of the thirteenth inverter circuit 948 is received at a second input of the second flip flop circuit 946. The output of the second flip flop circuit 946 is the link latch enable signal (LinkLatchEn) that is received at the fuse data link latch circuit 824.

The fuse data link latch circuit 824 includes a third flip flop circuit 950 that receives the data signal (FzDataLatched[n:0]) output from the fuse data latches circuit 806 at one input and the link enable signal (LinkLatchEn) at a second input. The link enable signal is also input into a fourteenth inverter circuit 952. The output of the fourteenth inverter circuit 952 is received at a third input of the third flip flop circuit 950. The output of the third flip flop circuit 950 is the fuse data bus.

The above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of fuse arrays configured to store information; and
a logic circuit configured to:
identify a start of a link loading operation based on a fuse bank address corresponding to a fuse array of the plurality of fuse arrays, the fuse bank address including a link loading start address;
receive link loading information associated with the link loading start address from the fuse array;
output the link loading information; and
for a duration of the link loading operation, output the link loading information for one or more subsequent fuse bank addresses.

2. The apparatus of claim 1, wherein the logic circuit is further configured to:
detect an end of the link loading operation; and
responsively output information received from the plurality of fuse arrays.

3. The apparatus of claim 2, wherein the logic circuit is configured to detect the end of the link loading operation based on a link loading end address, the link loading end address comprising a last fuse bank address in the one or more subsequent fuse bank addresses.

4. The apparatus of claim 2, wherein the logic circuit is configured to detect the end of the link loading operation based on a received end count value.

5. The apparatus of claim 2, wherein the logic circuit is configured to:
set a state of a flag signal to a first state based on detection of the start of the link loading operation; and
set the state of the flag signal to a second state based on detection of the end of the link loading operation, wherein the second state differs from the first state.

6. The apparatus of claim 1, wherein the link loading operation occurs during a broadcast operation in a memory device.

7. The apparatus of claim 1, wherein the logic circuit is configured to generate and output the fuse bank addresses.

8. The apparatus of claim 1, further comprising a plurality of fuse latch circuits configured to store the data output from the logic circuit.

9. An apparatus comprising:
a state machine configured to generate fuse bank addresses;
a link loading flag logic circuit configured to:
receive the fuse bank addresses;
detect a start of a link loading operation based on a fuse bank address including a link loading start address; and
set a state of a flag signal to a first state in response to detection of the start of the link loading operation; and
a fuse data select circuit configured to:
receive the flag signal and information from a fuse array based on the link loading start address, the information comprising link loading information;
based on the first state of the flag signal, latch the link loading information; and
output the link loading information for the link loading start address and for one or more fuse bank addresses received after the link loading start address while the flag signal remains in the first state.

10. The apparatus of claim 9, wherein:
the link loading flag logic circuit is configured to detect an end of the link loading operation and responsively set the state of the flag signal to a second state; and
based on the second state of the flag signal, the fuse data select circuit is configured to output information corresponding to one or more fuse bank addresses that are received after the end of the link loading operation.

11. The apparatus of claim 9, wherein the link loading flag logic circuit comprises:
a fuse bank address latch comprising one or more latch circuits; and
at least one link loading flag latch circuit configured to receive the fuse bank addresses and detect the link loading start address.

12. The apparatus of claim 11, wherein:
the at least one link loading flag latch circuit comprises a plurality of link loading flag latch circuits; and
the link loading flag logic circuit further comprises a logic circuit configured to receive flag signals output from the plurality of link loading flag latch circuits.

13. The apparatus of claim 11, wherein the at least one link loading flag latch circuit comprises:
a latch circuit;
a first decoder circuit configured to receive the fuse bank addresses and detect the link loading start address; and
a second decoder circuit configured to receive the fuse bank addresses and detect a link loading end address, wherein:
a state of a start signal output from the first decoder circuit transitions to a different state based on detection of the link loading start address, which causes a flag signal output from the latch circuit to transition to a first state; and
a state of a stop signal output from the second decoder circuit transitions to a different state based on detection of the link loading end address, which causes the flag signal output from the latch circuit to transition to a second state.

14. The apparatus of claim 11, wherein the at least one link loading flag latch circuit comprises:
a latch circuit;
a first decoder circuit configured to receive the fuse bank addresses and detect the link loading start address; and
a second decoder circuit configured to receive count values, wherein:
a state of a start signal output from the first decoder circuit transitions to a different state based on detection of the link loading start address, which causes a flag signal output from the latch circuit to transition to a first state; and
a state of a stop signal output from the second decoder circuit transitions to a different state based on receipt of an end count value, which causes the flag signal output from the latch circuit to transition to a second state.

15. A method comprising:
receiving information from a fuse array, the fuse array associated with a fuse bank address;
detecting a start of a link loading operation based on the fuse bank address;
storing the information, the information comprising link loading information;
transmitting the link loading information onto a fuse bus; and
for a subsequent fuse bank address produced after the fuse bank address, outputting the link loading information onto the fuse bus.

16. The method of claim 15, wherein:
the information comprises first information;
the fuse bank address comprises a first fuse bank address; and
the method further comprises:
detecting an end of the link loading operation;
receiving second information from the fuse array based on a second fuse bank address produced after the link loading operation; and
outputting the second information onto the fuse bus.

17. The method of claim 16, wherein:
the fuse bank address comprises a first fuse bank address; and
detecting the end of the link loading operation comprises detecting the end of the link loading operation based on a second fuse bank address.

18. The method of claim 16, wherein detecting the end of the link loading operation comprises detecting the end of the link loading operation based on a received end count value.

19. The method of claim 15, further comprising initiating a broadcast operation prior to receiving the information from the fuse array.

20. A memory device, comprising:
a fuse array configured to store information; and
a logic circuit configured to:
receive fuse bank addresses associated with the fuse array;
identify a start of a link loading operation based on a first fuse bank address, the first fuse bank address comprising a link loading start address;
receive and store information associated with the link loading start address from the fuse array, the information comprising link loading information;
output the link loading information onto a fuse bus;
during the link loading operation, output the link loading information onto the fuse bus for each fuse bank address received after the link loading start address;
detect an end of the link loading operation based on a second fuse bank address, the second fuse bank address comprising a link loading end address; and
output information received from the fuse array after detection of the link loading end address.

21. The memory device of claim 20, wherein the information comprises at least one of:
a row address in a memory array;
a column address in the memory array;
options data associated with an options circuit; or
bank data associated with a bank of the memory array.
